(19) United States
(12) Patent Application Publication
(10) Pub. No.: US 2009/0065485 A1
(43) Pub. Date: Mar. 12, 2009

(54) Plasma System

(75) Inventors: Liam O'Neill, Midleton (IE); Peter Dobbyn, Co Cork (IE); Walter Castagna, Co Cork (IE)

Correspondence Address: HOWARD & HOWARD ATTORNEYS PLLC, 450 West Fourth Street, Royal Oak, MI, 48067, US

(73) Assignee: DOW CORNING IRELAND LTD., Midleton, Co Cork, IE (IE)

(21) Appl. No.: 11/718,618

(22) PCT Filed: Nov. 3, 2005
(86) PCT No.: PCT/GB05/04246

§ 371 Date: May 4, 2007

(30) Foreign Application Priority Data
Nov. 5, 2004 (GB) GB0424532.0
Feb. 14, 2005 (GB) GB0502986.3

(51) Int. Cl. H05H 1/24; C23C 16/513

(52) U.S. Cl. 219/121.52; 219/121.47; 219/121.48; 427/569

(57) ABSTRACT

In a process for plasma treating a surface, a non-equilibrium atmospheric pressure plasma is generated within a dielectric housing having an inlet and an outlet through which a process gas flows from the inlet to the outlet. A tube formed at least partly of dielectric material extends outwardly from the outlet of the housing, whereby the end of the tube forms the plasma outlet. The surface to be treated is positioned adjacent to the plasma outlet so that the surface is in contact with the plasma and is moved relative to the plasma outlet.

The present invention relates to a plasma system or assembly and a method of treating a substrate using said assembly.

When matter is continually supplied with energy, its temperature increases and it typically transforms from a solid to a liquid and, then, to a gaseous state. Continuing to supply energy causes the system to undergo yet a further change of state in which neutral atoms or molecules of the gas are broken up by energetic collisions to produce negatively charged electrons, positive or negatively charged ions and other excited species. This mix of charged and other excited particles exhibiting collective behaviour is called “plasma”, the fourth state of matter. Due to their electrical charge, plasmas are highly influenced by external electromagnetic fields, which makes them readily controllable. Furthermore, their high energy content allows them to achieve processes which are impossible or difficult through the other states of matter, such as by liquid or gas processing.

The term “plasma” covers a wide range of systems whose density and temperature vary by many orders of magnitude. Some plasmas are very hot and all their microscopic species (ions, electrons, etc.) are in approximate thermal equilibrium, the energy input into the system being widely distributed through atomic/molecular level collisions. Other plasmas, however, particular those at low pressure (e.g. 100 Pa) where collisions are relatively infrequent, have their constituent species at widely different temperatures and are called “non-thermal equilibrium” plasmas. In these non-thermal plasmas the free electrons are very hot with temperatures of many thousands of Kelvin (K) whilst the neutral and ionic species remain cool. Because the free electrons have almost negligible mass, the total system heat content is low and the plasma operates close to room temperature thus allowing the processing of temperature sensitive materials, such as plastics or polymers, without imposing a damaging thermal burden onto the sample. However, the hot electrons create, through high energy collisions, a rich source of radicals and excited species with a high chemical potential energy capable of profound chemical and physical reactivity. It is this combination of low temperature operation plus high reactivity which makes non-thermal plasma technologically important and a very powerful tool for manufacturing and material processing, capable of achieving processes which, if achievable at all without plasma, would require very high temperatures or noxious and aggressive chemicals.

For industrial applications of plasma technology, a convenient method is to couple electromagnetic power into a volume of process gas. A process gas may be a single gas or a mixture of gases and vapours which is excitable to a plasma state by the application of the electromagnetic power. Workpieces/samples are treated by the plasma generated by being immersed or passed through the plasma itself or charged and/or excited species derived therefrom because the process gas becomes ionised and excited, generating species including chemical radicals, and ions as well as UV-radiation, which can react or interact with the surface of the workpieces/samples. By correct selection of process gas composition, driving power frequency, power coupling mode, pressure and other control parameters, the plasma process can be tailored to the specific application required by a manufacturer.

Because of the huge chemical and thermal range of plasmas, they are suitable for many technological applications. Non-thermal equilibrium plasmas are particularly effective for surface activation, surface cleaning, material etching and coating of surfaces.

Since the 1960s the microelectronics industry has developed the low pressure Glow Discharge plasma into an ultra-high technology and high capital cost engineering tool for semiconductor, metal and dielectric processing. The same low pressure Glow Discharge type plasma has increasingly penetrated other industrial sectors since the 1980s offering polymer surface activation for increased adhesion/bond strength, high quality degreasing/cleaning and the deposition of high performance coatings. Glow discharges can be achieved at both vacuum and atmospheric pressures. In the case of atmospheric pressure glow discharge, gases such as helium or argon are utilised as diluents and a high frequency (e.g. >1 kHz) power supply is used to generate a homogeneous glow discharge at atmospheric pressure via a Penning ionisation mechanism, (see for example, Kanazawa et al, J. Phys. D: Appl. Phys. 1988, 21, 838, Okazaki et al, Proc. Jpn. Symp. Plasma Chem. 1989, 2, 95, Kanazawa et al, Nuclear Instruments and Methods in Physical Research 1989, B37/38, 842, and Yokoyama et al., J. Phys. D: Appl. Phys. 1990, 23, 374).

Corona and flame (also a plasma) treatment systems have provided industry with atmospheric pressure plasma processing capability for about 30 years. However, despite their high manufacturability, these systems have failed to penetrate the market or be taken up by industry to anything like the same extent as the lower pressure, bath-processing-only plasma type. The reason is that corona/flame systems have significant limitations. Flame systems can be extremely effective at depositing coatings, but operate at high temperatures (>10,000 K). They are therefore only suitable for certain high temperature substrates such as metals and ceramics. Corona systems operate in ambient air, typically offering a single surface activation process (i.e. oxidation) and have a negligible effect on many materials and a weak effect on most. The treatment is often non-uniform as the corona discharge is a non-homogeneous discharge being generated between a point and plane electrode. The corona process is incompatible with thick webs or 3D workpieces.

A variety of “plasma jet” systems have been developed, as means of atmospheric pressure plasma treatment. Plasma jet systems generally consist of a gas stream which is directed between two electrodes. As power is applied between the electrodes, a plasma is formed and this produces a mixture of ions, radicals and active species which can be used to treat various substrates. The plasma produced by a plasma jet system is directed from the space between the electrodes (the plasma zone) as a flame-like phenomenon and can be used to treat remote objects.

U.S. Pat. Nos. 5,198,724 and 5,369,336 describe the first “cold” or non-thermal equilibrium atmospheric pressure plasma jet (hereafter referred to as APPJ), which consisted of an RF powered metal needle acting as a cathode, surrounded by an outer cylindrical anode. U.S. Pat. No. 6,429,400 describes a system for generating a blown atmospheric pressure glow discharge (APGD). This comprises a central electrode separated from an outer electrode by an electrical insulator tube. The inventor claims that the design does not generate the high temperatures associated with the prior art. Kang et al (Surf Coat. Technol., 2002, 171, 141-148) have also described a 13.56 MHz RF plasma source that operates by feeding helium or argon gas through two coaxial electrodes. In order to prevent an arc discharge, a dielectric material is loaded outside the central electrode. WO94/14303 describes a device in which an electrode cylinder has a pointed portion at the exit to enhance plasma jet formation.

U.S. Pat. No. 5,837,958 describes an APPJ based on coaxial metal electrodes where a powered central electrode and a dielectric coated ground electrode are utilised. A portion of the ground electrode is left exposed to form a bare ring electrode near the gas exit. The gas flow (air or argon) enters through the top and is directed to form a vortex, which keeps the arc confined and focused to form a plasma jet. To cover a wide area, a number of jets can be combined to increase the coverage.

Schutze et al (IEEE Trans. Plasma Sci., 1998, 26 (6), 1685) describe a device using concentric electrodes, though no dielectric was present between the electrodes. By using a high flow of helium (He) (typically 92 standard litres per minute (slm) as the process gas, it was possible to avoid arcing and generate a stable plasma flame.

U.S. Pat. No. 6,465,964 describes an alternative system for generating an APPJ, in which a pair of electrodes are placed around a cylindrical tube. Process gas enters through the top of the tube and exits through the bottom. When an AC electric field is supplied between the two electrodes, a plasma is generated by passing a process gas therebetween within the tube and this gives rise to an APPJ at the exit. The position of the electrodes ensures that the electric field forms in the axial direction. In order to extend this technology to the coverage of wide area substrates, the design can be modified, such that the central tube and electrodes are redesigned to have a rectangular tubular shape. This gives rise to a wide area plasma, which can be used to treat large substrates such as reel-to-reel plastic film.

Other authors have reported the formation of wide area plasma jets based on parallel plate technology. Gherardi, N. et. al., J. Phys D: Appl. Phys, 2000, 33, L104-L108 describe the production of a silica coating by passing a mixture of N₂, SiH₄ and N₂ through a dielectric barrier discharge (DBD) plasma formed between two parallel electrodes. The species exiting the reactor were allowed to deposit on a downstream substrate. EP1171900 describes a parallel plate reactor, which uses (RF) power to create a helium APGD. This is seen as an easily scaled up alternative to the concentric electrodes of the jet system. Another device consists of two perforated circular plates separated by a gap. The upper plate is connected to a 13.56 MHz RF power supply and the lower plate is grounded. A laminar flow of process gas is passed through the perforations in the top plate and enters the inter-electrode gap. Here the gas is ionised and a plasma forms. Arcing is prevented in the apparatus by using gas mixtures containing He (which limits ionisation), by using high flow velocities, and by properly spacing the RF-powered electrode. The process gas then exits the device through the perforations in the second electrode.

EP 0 431 951 describes a system for treating a substrate with the gases exiting a parallel plate reactor. This comprises flowing a gas through one or more parallel plate reactors and allowing the excited species to interact with a substrate placed adjacent to the gas exit.

Toshifuji et al (Surf. Coat. Technol., 2003, 171, 302-306) reported the formation of a cold arc plasma formed using a needle electrode placed inside a glass tube. A similar system has been reported by Dinescu et al. (Proceedings of ISPC 16, Taormina, Italy, June 2003). Janca et al. (Surf. Coat. Technol. 116-119 (1999), 547-551) describe a high frequency plasma ‘pencil’ in which a pencil-shaped dielectric with a built-in hollow electrode is used to generate a plasma at atmospheric, reduced or increased pressure. As an active material flowing through the plasma jet a gas, a liquid or a mixture of dispersed particles (powders) can be used.

U.S. Pat. No. 5,798,146 describes a single needle design that does not require the use of a counter electrode. Instead, a single sharp electrode is placed inside a tube and applying a high voltage to the electrode produces a leakage of electrons, which further react with the gas surrounding the electrode, to produce a flow or ions and radicals. As there is no second electrode, this does not result in the formation of an arc. Instead, a low temperature plasma is formed which is carried out of the discharge space by a flow of gas. Various nozzle heads have been developed to focus or spread the plasma. The system may be used to activate, clean or etch various substrates. Stoffels et al (Plasma Sources Sci. Technol., 2002, 11, 383-388) have developed a similar system for biomedical uses.

WO 02/028548 describes a method for forming a coating on a substrate by introducing an atomized liquid and/or solid coating material into an atmospheric pressure plasma discharge or an ionized gas stream resulting therefrom. WO 02/098962 describes coating a low surface energy substrate by exposing the substrate to a silicon compound in liquid or gaseous form and subsequently post-treating by oxidation or reduction using a plasma or corona treatment, in particular a pulsed atmospheric pressure glow discharge or dielectric barrier discharge. WO 03/085693 describes an atmospheric plasma generation assembly having one or more parallel electrode arrangements adapted for generating a plasma, means for introducing a process gas and an atomizer for atomizing and introducing a reactive agent. The assembly is such that the only exit for the process gas and the reactive agent is through the plasma region between the electrodes.

WO 03/097245 and WO 03/101621 describe applying an atomised coating material onto a substrate to form a coating. The atomised coating material, upon leaving an atomizer such as an ultrasonic nozzle or a nebuliser, passes through an excited medium (plasma) to the substrate. The substrate is positioned remotely from the excited medium. The plasma is generated in a pulsed manner.

Many plasma jet type designs cannot be used to treat conductive substrates, especially grounded metal substrates, if the distance between the electrode and the substrate is too small. There is a tendency for the plasma to break down and form a high temperature arc between the powered electrode(s) and the substrate. In effect, the substrate acts as a counter electrode. However, if the distance between the electrode and the substrate is sufficient (˜150 mm or more), then a stable plasma jet can be formed. But in order to treat a substrate placed at such a distance, the jet has to be stable over quite a long distance. It has been found that irrespective of the process gas used, the plasma jet is quenched upon exposure to air and this limits the length of most jets. One method to extend the length of the flame is to minimise the air entrainment. This can be achieved by maintaining a laminar gas flow. Turbulent gas flow maximises mixing with air and rapidly quenches the plasma. However, even with a laminar flow, the plasma jet is usually less than 75 mm.

In a first embodiment of the invention the inventors have shown that the non-equilibrium discharge from the plasma which may be referred to as flame-like could be stabilized over considerable distances by confining it to a long length of tubing. This prevents air mixing and minimises quenching of the flame-like non-equilibrium plasma discharge. The flame-like non-equilibrium plasma discharge extends at least to the outlet, and usually beyond the outlet, of the tubing.

Thus in a process according to the invention for plasma treating a surface, a non-equilibrium atmospheric pressure plasma is generated within a dielectric housing having an inlet and an outlet through which a process gas flows from the inlet to the outlet, a tube formed at least partly of dielectric material extends outwardly from the outlet of the housing, whereby the end of the tube forms the plasma outlet, and the surface to be treated is positioned adjacent to the plasma outlet so that the surface is in contact with the plasma and is moved relative to the plasma outlet.

An apparatus for plasma treating a surface comprises
a dielectric housing having an inlet and an outlet,
means for causing a process gas to flow from the inlet to the outlet,
means for generating a non-equilibrium atmospheric pressure plasma in the process gas, a tube formed at least partly of dielectric material extending outwardly from the outlet of the housing, whereby the end of the tube forms the plasma outlet, and means for moving the surface to be treated relative to the plasma outlet while maintaining the surface adjacent to the plasma outlet.

The use of an outwardly extending tube according to the invention extends the length of the flame-like non-equilibrium atmospheric pressure plasma discharge beyond that which can otherwise be achieved with the particular process gas used. Using helium or argon as process gas, it is possible to create a flame-like discharge that extends for at least 150 mm. and often more than 300 mm. and can be used to treat conductive substrates, even grounded metallic pieces.

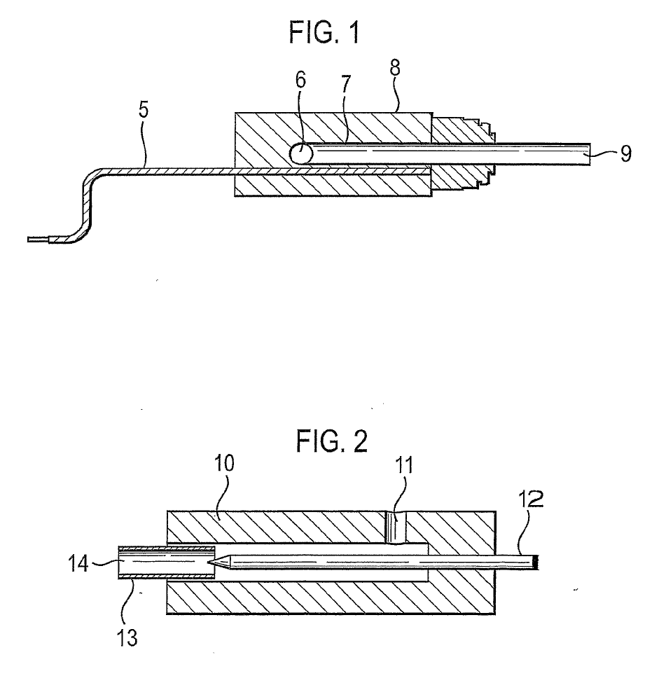

FIG. 1 is a diagrammatic cross-section of an apparatus for plasma treating a surface according to the invention

FIG. 2 is a diagrammatic cross-section of an alternative apparatus for plasma treating a surface according to the invention

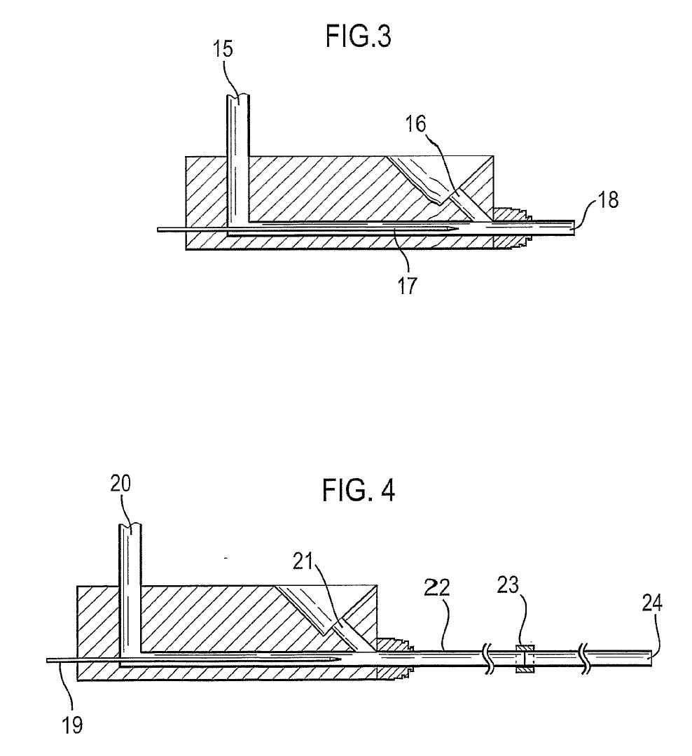

FIG. 3 is a diagrammatic cross-section of another alternative apparatus for plasma treating a surface according to the invention

FIG. 4 is a diagrammatic cross-section of an apparatus as shown in FIG. 3 with a longer tube extending from the plasma generating device

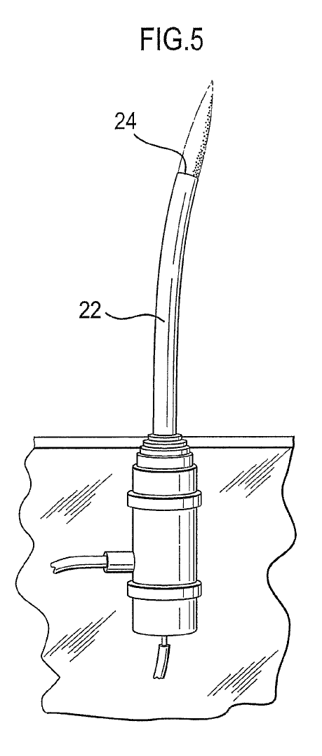

FIG. 5 is a view of an apparatus as shown in FIG. 4 in use with an argon plasma jet

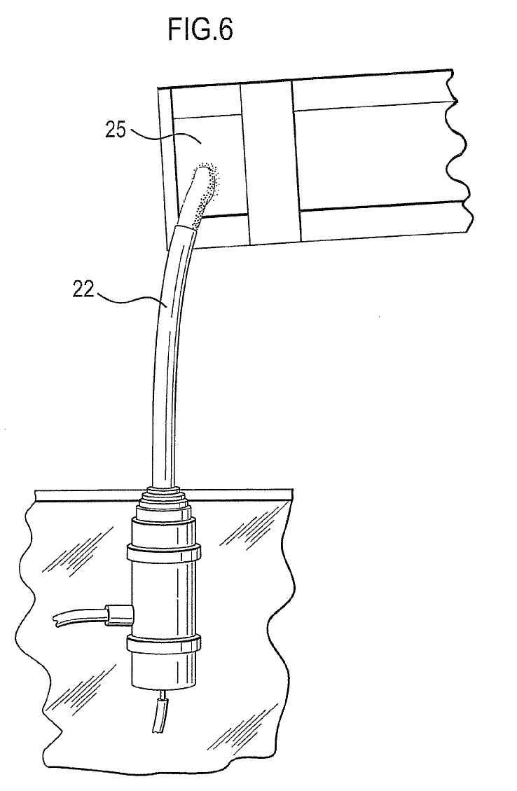

FIG. 6 is a view of the apparatus of FIG. 5 being used for spot treatment of a metal substrate

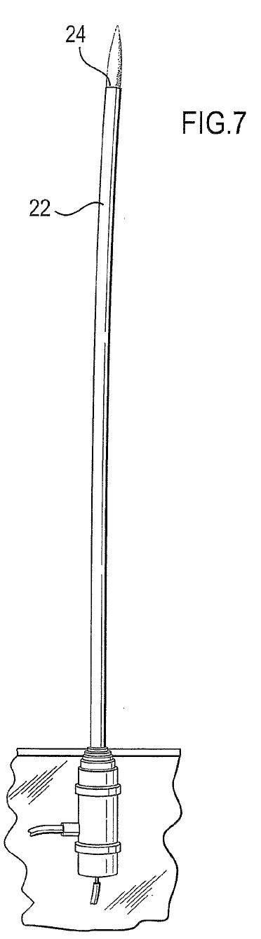

FIG. 7 is a view of an apparatus as shown in FIG. 4 in use with a helium plasma jet

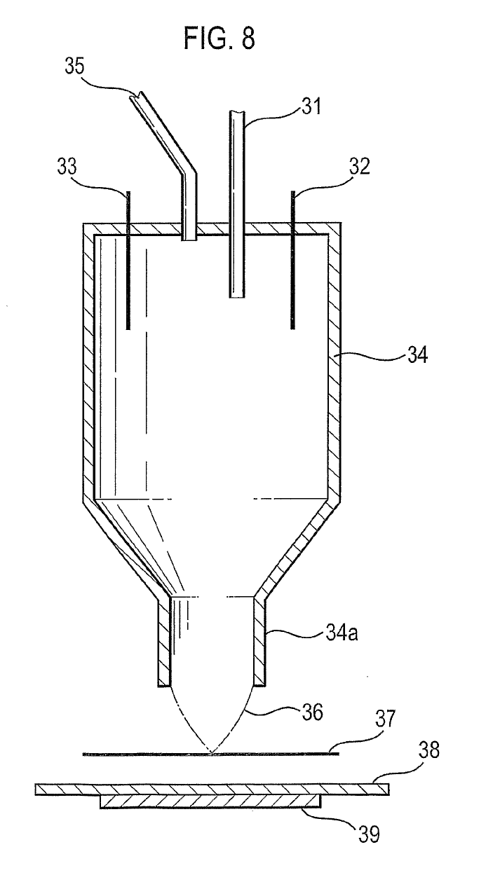

FIG. 8 is a diagrammatic cross-section of an alternative plasma generating device for use in the apparatus of FIG. 1

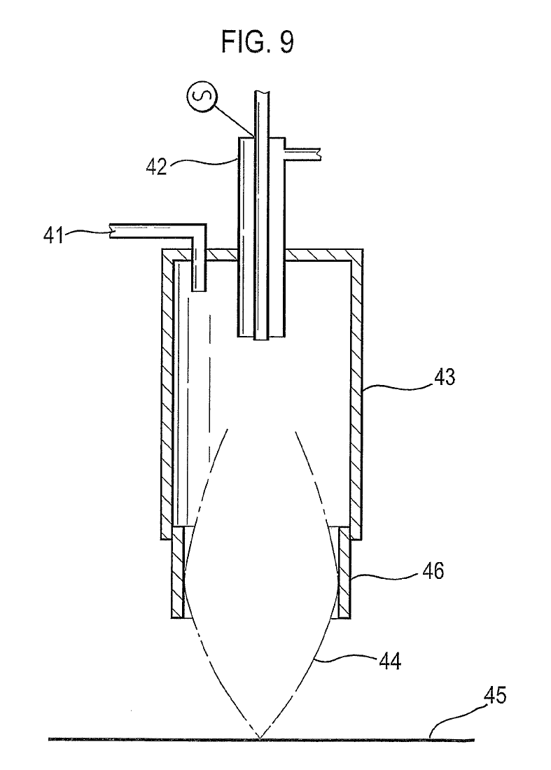

FIG. 9 is a diagrammatic cross-section of another alternative plasma generating device for use in the apparatus of FIG. 1

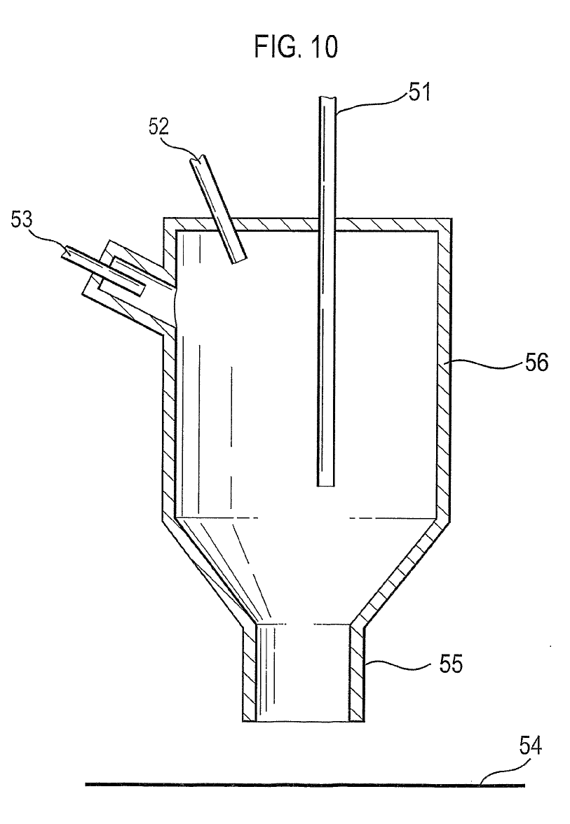

FIG. 10 is a diagrammatic cross-section of a further alternative plasma generating device for use in the apparatus of FIG. 1

The plasma can in general be any type of non-equilibrium atmospheric pressure plasma such as a dielectric barrier discharge plasma, a corona discharge, a diffuse dielectric barrier discharge or a glow discharge plasma. A diffuse dielectric barrier discharge plasma or glow discharge plasma is preferred. Preferred processes are “low temperature” plasmas wherein the term “low temperature” is intended to mean below 200° C., and preferably below 100° C. These are plasmas where collisions are relatively infrequent (when compared to thermal equilibrium plasmas such as flame based systems) which have their constituent species at widely different temperatures (hence the general name “non-thermal equilibrium” plasmas).

One preferred device according to the invention for generating a non-equilibrium atmospheric pressure plasma has only a single electrode. Despite the lack of a counter electrode, the device still gives rise to a non-equilibrium plasma flame. The presence of a powered electrode in the vicinity of a working gas such as helium is sufficient to generate a strong RF field which can give rise to a plasma ionisation process and forms an external plasma jet.

One example of such a device having only a single electrode is shown in FIG. 1. This design consists of a tube (7), surrounded by a suitable dielectric material (8). The tube (7) extends beyond the dielectric housing (8). The process gas, optionally containing an atomized surface treatment agent, enters an opening (6). A single electrode (5) is placed outside the tube and this is encased in a layer of the dielectric material (8). The electrode is connected to a suitable power supply. No counter electrode is required. When power is applied, local electric fields form around the electrode. These interact with the gas within the tube and a plasma is formed, which extends to and beyond an aperture (9) at the end of tube (7).

In an alternative design having improved capability to form nitrogen plasma jets as well as helium and argon plasma jets, and improved firing of the plasma, a bare metal electrode is used. A single, preferably sharp, electrode is housed within a dielectric housing such as a plastic tube through which the process gas and optionally an aerosol (atomised surface treatment agent) flow. As power is applied to the needle electrode, an electric field forms and the process gas is ionised.

This can be better understood by referring to FIG. 2. This shows a metal electrode (12) housed within a suitable chamber (10). This chamber may be constructed from a suitable dielectric material such as polytetrafluoroethylene. The process gas and aerosol enter into the chamber through one or more apertures (11) in the housing. As an electric potential is applied to the electrode, the process gas becomes ionised, and the resultant plasma is directed so that it extends out through an opening (14) of an exit pipe (13). By adjusting the size and shape of the exit pipe (13), the size, shape and length of the plasma flame can be adjusted.

The use of a metal electrode with a sharp point facilitates plasma formation. As an electric potential is applied to the electrode, an electric field is generated which accelerates charged particles in the gas forming a plasma. The sharp point aids the process, as the electric field density is inversely proportional to the radius of curvature of the electrode. The electrode can also give rise to a leakage of electrons into the gas due to the high secondary electron emission coefficient of the metal. As the process gas moves past the electrode, the plasma species are carried away from the electrode to form a plasma jet.

In a still further embodiment of the present invention the plasma jet device consists of a single hollow electrode, without any counter electrode. A gas is blown through the centre of the electrode. RF power is applied and this leads to the formation of strong electromagnetic fields in the vicinity of the electrode. This causes the gas to ionise and a plasma forms which is carried through the electrode and exits as a plasma flame. The narrow nature of this design allows for focussed, narrow plasmas to be generated under ambient conditions for depositing functional coatings on a three-dimensionally shaped substrate.

More generally, the electrode or electrodes can take the form of pins, plates, concentric tubes or rings, or needles via which gas can be introduced into the apparatus. A single electrode can be used, or a plurality of electrodes can be used. The electrodes can be covered by a dielectric, or not covered by a dielectric. If multiple electrodes are used, they can be a combination of dielectric covered and non-covered electrodes. One electrode can be grounded or alternatively no electrodes are grounded (floating potential). If no electrodes are grounded, the electrodes can have the same polarity or can have opposing polarity. A co-axial electrode configuration can be used in which a first electrode is placed co-axially inside a second electrode. One electrode is powered and the other may be grounded, and dielectric layers can be included to prevent arcing, but this configuration is less preferred.

The electrode may be made of any suitable metal and can for example be in the form of a metal pin e.g. a welding rod, or a flat section.

Electrodes can be coated or incorporate a radioactive element to enhance ionisation of the plasma. A radioactive metal may be used, for example the electrode can be formed from tungsten containing 0.2 to 20% by weight, preferably about 2%, radioactive thorium. This promotes plasma formation through the release of radioactive particles and radiation which can initiate ionisation. Such a doped electrode provides more efficient secondary electron emission and therefore device is easy to strike.

The power supply to the electrode or electrodes is a radio frequency power supply as known for plasma generation, that is in the range 1 kHz to 300 GHz. Our most preferred range is the very low frequency (VLF) 3 kHz-30 kHz band, although the low frequency (LF) 30 kHz-300 kHz range can also be used successfully. One suitable power supply is the Haiden Laboratories Inc. PHF-2K unit which is a bipolar pulse wave, high frequency and high voltage generator. It has a faster rise and fall time (<3 μs) than conventional sine wave high frequency power supplies. Therefore, it offers better ion generation and greater process efficiency. The frequency of the unit is also variable (1-100 kHz) to match the plasma system. The voltage of the power supply is preferably at least 1 kV up to 10 kV or more.

When the PHF-2K power supply was connected to the single electrode design of plasma generating device shown in FIG. 1 and a range of experiments were carried out, it was found that stable helium and argon plasma jets were readily formed. In order to generate an argon flame, it was found to be much easier to fire a helium plasma jet and then switch over to argon. When the PHF-2K power supply was connected to the single electrode design of plasma generating device shown in FIG. 2, it was possible to produce plasma jets using a range of process gases, including helium, argon, oxygen, nitrogen, air and mixtures of said gases.

The dielectric housing can be of any electrically non-conductive, e.g. plastics, material. For example in the device of FIG. 2 a single sharp electrode is housed within a plastic tube, for example of polyamide, polypropylene or PT FE, through which the aerosol and process gas flow.

When using the device of FIG. 1, the choice of dielectric material for tube (7) was found to have an important influence. When polyamide was used as the dielectric material, the plasma rapidly became too hot and the pipe overheated. Similar problems were encountered with polypropylene. Replacing the polyamide with PTFE removed this problem. A rigid dielectric can be used for the tube (7) or for the housing (8) or (10) by replacing the plastic with alumina.

In general the process gas used to produce the plasma can be selected from a range of process gases, including helium, argon, oxygen, nitrogen, air and mixtures of said gases with each other or with other materials. Most preferably the process gas comprises an inert gas substantially consisting of helium, argon and/or nitrogen, that is to say comprising at least 90% by volume, preferably at least 95%, of one of these gases or a mixture of two or more of them, optionally with up to 5 or 10% of another gas or entrained liquid droplets or powder particles.

In general, plasmas can be fired at lower voltages using helium as process gas than with argon and at lower voltages using argon than with nitrogen or air. Using the sharp electrode device of FIG. 2, pure argon plasmas can be directly ignited at 3 kV using the PHF-2K power supply. If a blunt metal electrode is used in place of the sharp electrode in the apparatus of FIG. 2, then an argon plasma can be fired at 5 kV. With the single electrode design of FIG. 1, a voltage of at least 6.5 kV is required.

The use of a length of tubing extending outwardly from the outlet of the dielectric housing allows a flame-like non-equilibrium atmospheric pressure plasma discharge to be stabilized over considerable distances. Using such a system, it is possible to create a flame-like discharge that extends for at least 150 mm or even over 300 mm. The system can be used to treat conductive or semiconductive substrates, even grounded electrically conductive substrates such as metallic pieces. In the apparatus of FIG. 1 that portion of the tube (9) extending beyond the housing (8) acts as the tube extending the plasma flame. In the apparatus of FIG. 2 the exit pipe (13) acts as the tube extending the plasma flame. Use of a sufficiently long tube allows the discharge generated by the plasma can be extended for a distance of over one metre in length by confining the plasma within the tube. The powered electrodes are kept at a sufficient distance from the grounded substrate to prevent an arc from forming.

The tube extending the plasma flame is formed at least partly of dielectric material such as plastics, for example polyamide, polypropylene or PTFE. The tube is preferably flexible so that the plasma outlet can be moved relative to the substrate. In order to stabilise the plasma jet over lengths greater than 300 mm, it is beneficial to use conductive cylinders, preferably with sharp edges, to connect adjacent pieces of pipe. These cylinders are preferably not grounded. Preferably, these rings have a round sharp edge on both sides. As it passes inside these metal cylinders, the process gas is in contact with metal. The free electrons created inside the plasma region induce a strong electric field near sharp conductive edges that ionize further the process gas inside the pipe. The sharp edge on the other side of the cylinder creates a strong electric field that initiates the ionization of the gas in the following pipe section. In this way the plasma inside the pipe is extended. Use of multiple metal connectors enables the plasma to be extended over several metres, for example 3 to 7 metres. There is a limit on the maximum length of plasma that can be obtained due to the voltage drop caused by the resistance of the plasma to the current passage.

The apparatus of FIG. 2 was used with and without a tube or pipe (13) extending 200 mm beyond the housing (10) to demonstrate the quality of the plasma jet with each plasma gas. In order to directly compare different gases, a set of standard conditions were chosen and the properties of each plasma jet were evaluated for each gas. The results are shown in Table 1 below. The helium jet is the most stable and coldest plasma, though there is very little difference when compared to argon. Nitrogen and air plasmas are less stable and run at higher temperatures.

TABLE 1
Effect of process gas on plasma jet properties

| Process Gas | Length of Jet | Length of Jet in tube | Temperature |
|---|---|---|---|
| Helium | 20 mm | >200 mm | <40° C. |
| Argon | 20 mm | >200 mm | <50° C. |
| Nitrogen | 15 mm | 30 mm | >70° C. |
| Air | 4 mm | 10 mm | >70° C. |

As can be seen from Table 1, the use of a tube extending outwardly from the outlet of the dielectric housing extends the length of the plasma jet considerably. The length of a helium or argon plasma jet is extended to over 200 mm. (flame extended beyond the end of tube (13)). This could be extended further by use of a longer tube. The length of a nitrogen plasma jet using the tube (13) was longer than a helium or argon plasma jet without tube (13).

In many preferred processes for plasma treating a surface, the plasma contains an atomised surface treatment agent. For example, when a polymerisable precursor is introduced into the plasma jet, preferably as an aerosol, a controlled plasma polymerisation reaction occurs which results in the deposition of a plasma polymer on any substrate which is placed adjacent to the plasma outlet of the tube. Using the process of the invention, a range of functional coatings have been deposited onto numerous substrates. These coatings are grafted to the substrate and retain the functional chemistry of the precursor molecule.

FIG. 3 shows a modified version of the pin type electrode system shown in FIG. 2. In FIG. 3, the process gas enters upstream (15) of the plasma. An atomised surface treatment agent can be incorporated in the flow of process gas (15). In an alternative design, the aerosol of atomised surface treatment agent is introduced directly into the plasma. This is achieved by having a second gas entry point (16) located close to the tip of the electrode (17). The aerosol can be added directly at this point (16), with the main process gas still entering upstream of the plasma region (15). Alternatively, some (or all) of the process gas can also be added with the aerosol adjacent to the tip of the electrode. Using this setup, the plasma and precursor exit though a suitable tube (18) extending from the outlet of the dielectric housing surrounding the electrode (17).

FIG. 4 shows a preferred device which generates long plasmas for the treatment of conducting substrates or of the inside of 3-d objects or tubes. As in FIG. 3, a powered electrode (19) interacts with a process gas (20) and aerosol (21) to produce a plasma. The length of the plasma is extended by confining the plasma to a tube (22) as it leaves the device. As long as the plasma is confined within this tube, then the plasma is not quenched by interaction with the external atmosphere. In order to further extend the plasma length, conductive pieces (23) are incorporated into the tube (22) to connect adjacent pieces of the tube. The conductive metal rings (23) have a round sharp edge on both sides. The resulting plasma may be extended over a considerable distance before exiting through plasma outlet (24).

FIG. 5 is a view of an apparatus of the type described in FIG. 4 in use. Argon is used as process gas and the plasma flame extends beyond the outlet (24) of tube (22).

FIG. 6 is a view of the apparatus of FIG. 5 with the argon plasma flame being used to treat a metal substrate (25). There is no arcing between the electrode (19) and the metal substrate (25). FIG. 7 is a view of the same apparatus in use with helium as process gas. An even longer tube (22) is used and the flame still extends beyond the outlet (24). The plasma preferably contains an atomized surface treatment agent. The atomised surface treatment agent can for example be a polymerisable precursor. When a polymerisable precursor is introduced into the plasma jet, preferably as an aerosol, a controlled plasma polymerisation reaction occurs which results in the deposition of a plasma polymer on any substrate which is placed adjacent to the plasma outlet. Using the process of the invention, a range of functional coatings have been deposited onto numerous substrates. These coatings are grafted to the substrate and retain the functional chemistry of the precursor molecule.

An advantage of using a diffuse dielectric barrier discharge or an atmospheric pressure glow discharge assembly for the plasma treating step of the present invention as compared with the prior art is that both liquid and solid atomised polymerisable monomers may be used to form substrate coatings, due to the method of the present invention taking place under conditions of atmospheric pressure. Furthermore, the polymerisable monomers can be introduced into the plasma discharge or resulting stream in the absence of a carrier gas. The precursor monomers can be introduced directly by, for example, direct injection, whereby the monomers are injected directly into the plasma.

It is to be understood that the surface treatment agent in accordance with the present invention is a precursor material which is reactive within the atmospheric pressure plasma or as part of a plasma enhanced chemical vapour deposition (PE-CVD) process and can be used to make any appropriate coating, including, for example, a material which can be used to grow a film or to chemically modify an existing surface. The present invention may be used to form many different types of coatings. The type of coating which is formed on a substrate is determined by the coating-forming material(s) used, and the present method may be used to (co)polymerise coating-forming monomer material(s) onto a substrate surface.

The coating-forming material may be organic or inorganic, solid, liquid or gaseous, or mixtures thereof. Suitable organic coating-forming materials include carboxylates, methacrylates, acrylates, styrenes, methacrylonitriles, alkenes and dienes, for example methyl methacrylate, ethyl methacrylate, propyl methacrylate, butyl methacrylate, and other alkyl methacrylates, and the corresponding acrylates, including organofunctional methacrylates and acrylates, including poly(ethyleneglycol) acrylates and methacrylates, glycidyl methacrylate, trimethoxysilyl propyl methacrylate, allyl methacrylate, hydroxyethyl methacrylate, hydroxypropyl methacrylate, dialkylaminoalkyl methacrylates, and fluoroalkyl (meth)acrylates, for example heptadecylfluorodecyl acrylate (HDFDA) of the formula

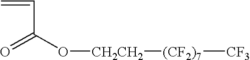

or pentafluorobutyl acrylate, methacrylic acid, acrylic acid, fumaric acid and esters, itaconic acid (and esters), maleic anhydride, styrene, α-methylstyrene, halogenated alkenes, for example, vinyl halides, such as vinyl chlorides and vinyl fluorides, and fluorinated alkenes, for example perfluoroalkenes, acrylonitrile, methacrylonitrile, ethylene, propylene, allyl amine, vinylidene halides, butadienes, acrylamide, such as N-isopropylacrylamide, methacrylamide, epoxy compounds, for example glycidoxypropyltrimethoxysilane, glycidol, styrene oxide, butadiene monoxide, ethyleneglycol diglycidylether, glycidyl methacrylate, bisphenol A diglycidylether (and its oligomers), vinylcyclohexene oxide, conducting polymers such as pyrrole and thiophene and their derivatives, and phosphorus-containing compounds, for example dimethylallylphosphonate. The coating forming material may also comprise acryl-functional organosiloxanes and/or silanes.

Suitable inorganic coating-forming materials include metals and metal oxides, including colloidal metals. Organometallic compounds may also be suitable coating-forming materials, including metal alkoxides such as titanates, tin alkoxides, zirconates and alkoxides of germanium and erbium. We have found that the present invention has particular utility in providing substrates with siloxane-based coatings using coating-forming compositions comprising silicon-containing materials. Suitable silicon-containing materials for use in the method of the present invention include silanes (for example, silane, alkylsilanes, alkylhalosilanes, alkoxysilanes) and linear (for example, polydimethylsiloxane or polyhydrogenmethylsiloxane) and cyclic siloxanes (for example, octamethylcyclotetrasiloxane), including organo-functional linear and cyclic siloxanes (for example, Si—H containing, halo-functional, and haloalkyl-functional linear and cyclic siloxanes, e.g. tetramethylcyclotetrasiloxane and tri(nonofluorobutyl)trimethylcyclotrisiloxane). A mixture of different silicon-containing materials may be used, for example to tailor the physical properties of the substrate coating for a specified need (e.g. thermal properties, optical properties, such as refractive index, and viscoelastic properties).

The atomiser preferably uses a gas to atomise the surface treatment agent. The electrode can be combined with the atomiser within the housing. Most preferably, the process gas used for generating the plasma is used as the atomizing gas to atomise the surface treatment agent. The atomizer can for example be a pneumatic nebuliser, particularly a parallel path nebuliser such as that sold by Burgener Research Inc. of Mississauga, Ontario, Canada, or that described in U.S. Pat. No. 6,634,572, or it can be a concentric gas atomizer. The atomizer can alternatively be an ultrasonic atomizer in which a pump is used to transport the liquid surface treatment agent into an ultrasonic nozzle and subsequently it forms a liquid film onto an atomising surface. Ultrasonic sound waves cause standing waves to be formed in the liquid film, which result in droplets being formed. The atomiser preferably produces drop sizes of from 10 to 100 μnm, more preferably from 10 to 50 μm. Suitable atomisers for use in the present invention are ultrasonic nozzles from Sono-Tek Corporation, Milton, N.Y., USA. Alternative atomisers may include for example electrospray techniques, methods of generating a very fine liquid aerosol through electrostatic charging. The most common electrospray apparatus employs a sharply pointed hollow metal tube, with liquid pumped through the tube. A high-voltage power supply is connected to the outlet of the tube. When the power supply is turned on and adjusted for the proper voltage, the liquid being pumped through the tube transforms into a fine continuous mist of droplets. Inkjet technology can also be used to generate liquid droplets without the need of a carrier gas, using thermal, piezoelectric, electrostatic and acoustic methods.

In one embodiment of the invention the electrode is combined with the atomizer in such a way that the atomizer acts as the electrode. For example, if a parallel path atomizer is made of conductive material, the entire atomizer device can be used as an electrode. Alternatively a conductive component such as a needle can be incorporated into a non-conductive atomizer to form the combined electrode-atomiser system.

In the apparatus of FIG. 8, an atomizing device (31), which can be a pneumatic nebuliser or an ultrasonic atomizer, is positioned with its exit between two electrodes (32) and (33) within a dielectric housing (34) extending as a tube (34a) at its lower end. The housing has an inlet (35) for a process gas such as helium or argon so that the gas flows between the electrodes (32, 33) approximately parallel to the atomized liquid from atomizer (31). A non-equilibrium plasma flame (36) extends from the electrodes (32, 33) beyond the outlet of the tube (34a). A metal substrate (37), backed by a dielectric sheet (38) and a grounded metal support (39), is positioned adjacent the flame (36) at the outlet of the tube (34a). When a polymerisable surface treatment agent is atomized in atomizer (31) and a radio frequency high voltage is applied to electrodes (32, 33), the substrate (37) is treated with a plasma polymerized coating.

In the apparatus of FIG. 9, a process gas inlet (41) and an atomizing device (42) both feed into a dielectric housing (43), having a tube (46) extending from its outlet, so that the process gas and the atomized liquid flow approximately parallel. The atomizing device (42) has gas and liquid inlets and is formed of electrically conductive material such as metal. A radio frequency high voltage is applied to the atomizer (42) so that it acts as an electrode and a plasma jet (44) is formed extending to the outlet of the tube (46). A substrate (45) is positioned adjacent to the outlet of the tube (46) to be plasma treated with the surface treatment agent atomized in atomizer (42).

In the apparatus of FIG. 10, an electrode (51) is positioned within a housing (56) having a tube (55) extending from its outlet. A process gas inlet (52) and an aerosol (53) both feed into the housing in the region of the electrode (51). When a polymerisable surface treatment agent is atomized in aerosol (53) and a radio frequency high voltage is applied to electrode (51), a plasma flame is formed extending to the outlet of the tube (55), and a substrate (54) positioned adjacent the outlet is treated with a plasma polymerized coating.

The apparatus of the present invention may include a plurality of atomisers, which may be of particular utility, for example, where the apparatus is to be used to form a copolymer coating on a substrate from two different coating-forming materials, where the monomers are immiscible or are in different phases, e.g. the first is a solid and the second is a gas or liquid.

The plasma apparatus and processes of the present invention as hereinbefore described may be used for plasma treating any suitable substrate, including complex shaped objects. Applications include coating 3D objects such as tubing or bottles or coatings on the inside of a bottle particularly barrier coatings. Examples include medical devices and implants, including the internal and external coating/treatment of catheters, drug delivery devices, dosage devices, clinical diagnostics, implants such as cardio and prosthetic implants, syringes, needles, particularly hypodermic needles, walls and flooring, woundcare products, tubing including medical tubing, powders and particles. Other applications include coating complex shaped components such as electronic components, or print adhesion enhancement, or the coating of wire, cable or fibres. The system can be used as a focused plasma to enable creation of patterned surface treatments.

Furthermore a plasma jet device may be used to treat the internal wall of a pipe or other three dimensional body by transporting the discharge, generated by the formation of a plasma by an electrode system in accordance with the present invention, down a tube, preferably made of polytetrafluoroethylene (PTFE), of the type shown in FIG. 3 or 4. This PTFE tube is placed inside the pipe which is to be coated. A plasma is activated and where appropriate a coating precursor material is injected into the plasma in the form of a gas or aerosol or the like. The PTFE or like tube is gradually drawn through the pipe/tubing, whilst depositing a uniform coating on the internal surface of the pipe. To improve the coating uniformity, either the PTFE tube or the pipe/tubing may be rotated. The device can be small and portable, with a low cost replaceable nozzle for ease of cleaning/maintenance.

Three dimensional products which may require internal coatings include packaging products such as bottles, containers, caps and closures, boxes, cartons, pouches and blister packs, and profiled and preformed plastics and laminates.

Electronics equipment which may be coated using the apparatus and process of the invention includes textile and fabric based electronics printed circuit boards, displays including flexible displays, and electronic components such as resistors, diodes, capacitors, transistors, light emitting diodes (leds), organic leds, laser diodes, integrated circuits (ic), ic die, ic chips, memory devices logic devices, connectors, keyboards, semiconductor substrates, solar cells and fuel cells. Optical components such as lenses, contact lenses and other optical substrates may similarly be treated. Other applications include military, aerospace or transport equipment, for example gaskets, seals, profiles, hoses, electronic and diagnostic components, household articles including kitchen, bathroom and cookware, office furniture and laboratory ware.

Using a small hypodermic type needle will generate a microbore thin stable discharge to facilitate activating and coating very precise areas of a body—e.g. electrical components. Wide area coatings can be achieved by offsetting devices.

Any suitable coatings may be applied using the apparatus and process of the invention, for example coatings for surface activation, anti-microbial, friction reduction (lubricant), bio-compatible, corrosion resistant, oleophobic, hydrophilic, hydrophobic, barrier, self cleaning, trapped actives and print adhesion.

Trapped active materials may be applied on to substrate surfaces by means of the present equipment and processes. The term ‘active material(s)’ as used herein is intended to mean one or more materials that perform one or more specific functions when present in a certain environment. They are chemical species which do not undergo chemical bond forming reactions within a plasma environment. It is to be appreciated that an active material is clearly discriminated from the term “reactive”; a reactive material or chemical species is intended to mean a species which undergoes chemical bond forming reactions within a plasma environment. The active may of course be capable of undergoing a reaction after the coating process.

Any suitable active material may be utilised providing it substantially does not undergo chemical bond forming reactions within a plasma. Examples of suitable active materials include anti-microbials (for example, quaternary ammonium and silver based), enzymes, proteins, DNA/RNA, pharmaceutical materials, UV screen, anti-oxidant, flame retardant, cosmetic, therapeutic or diagnostic materials antibiotics, anti-bacterials, anti-fungals, cosmetics, cleansers, growth factors, aloe, and vitamins, fragrances & flavours; agrochemicals (pheromones, pesticides, herbicides), dyestuffs and pigments, for example photochromic dyestuffs and pigments and catalysts.

The chemical nature of the active material(s) used in the present invention is/are generally not critical. They can comprise any solid or liquid material which can be bound in the composition and where appropriate subsequently released at a desired rate.

The invention is illustrated by the following Examples

### EXAMPLE 1

Using the apparatus of FIG. 8, fluorocarbon coatings were deposited onto a range of substrates from pentafluorobutyl acrylate CH₂═CH—COO—CH₂CH₂CF₂CF₃ as precursor. The substrate was positioned adjacent to the plasma flame outlet (24) of tube (22) and the tube was moved across the substrate. A fluorocarbon coating was deposited onto glass using the following conditions; power supply 550 W, 14.8 kV, 100 kHz; process gas flow (15) 20 standard litres per minute (slm) Argon containing 2.5 μl/min of the fluorocarbon precursor surface treatment agent. The plasma jet was quite cold (less than 40° C.), and gives rise to a soft polymerisation process. Although coatings could be deposited at higher fluorocarbon concentrations, we found that the use of low precursor flows such as 1 to 5 or 10 μl/min produced the best coatings. The coating deposited was oleophobic and hydrophobic.

Using the same conditions, hydrophobic and oleophobic fluorocarbon coatings were deposited onto plastic (polypropylene film), metal and ceramic (silica) substrates.

### EXAMPLE 2

Example 1 was repeated using helium in place of argon at the same flow rates.

Hydrophobic and oleophobic fluorocarbon coatings were plasma deposited onto plastic, glass, metal and ceramic substrates.

### EXAMPLE 3

Examples 1 and 2 were repeated using HDFDA as the fluorocarbon precursor surface treatment agent. Hydrophobic and oleophobic fluorocarbon coatings were plasma deposited onto all the substrates. The coatings deposited onto polished metal discs were evaluated as low friction coatings. A pin on disc method was used to evaluate the friction and wear characteristics of the coating. A tungsten carbide pin was used with a 50 g load. The sample to be tested was placed in contact with the pin and the sample rotates. By monitoring the friction versus the number of revolutions, the wear rate can be deduced. The coatings displayed significant resistance to abrasion.

### EXAMPLE 4

The process of Example 1 was repeated using polyhydrogenmethylsiloxane in place of the fluorocarbon as the surface treatment agent for polypropylene film. This produced a coating with a water contact angle in excess of 130°. FTIR analysis showed that the coating retained the functional chemistry of the precursor, with the reactive Si—H functional group giving rise to a peak at 2165 cm⁻¹.

### EXAMPLE 5

The process of Example 4 was repeated using polyethylene glycol (PEG) methacrylate in place of the siloxane. This produced a hydrophilic coating of poly (PEG methacrylate) on the polypropylene film.

1. A process for plasma treating a surface, characterised in that a non-equilibrium atmospheric pressure plasma is generated within a dielectric housing having an inlet and an outlet through which a process gas flows from the inlet to the outlet, a tube formed at least partly of dielectric material extends outwardly from the outlet of the housing, whereby the end of the tube forms the plasma outlet and the plasma extends from the electrode to the plasma outlet, and the surface to be treated is positioned adjacent to the plasma outlet so that the surface is in contact with the plasma and is moved relative to the plasma outlet.

2. A process according to claim 1, characterised in that the tube is flexible and is moved across the surface to be treated.

3. A process according to claim 1, characterised in that the plasma extends for a distance of at least 30 mm from the tip of the electrode to the plasma outlet.

4. A process according to claim 3, characterised in that the surface to be treated is an electrically conductive or semiconductive surface and the plasma extends for a distance of at least 150 mm from the tip of the electrode to the plasma outlet.

5. A process according to claim 3, characterised in that the tube comprises lengths of dielectric material joined by conductive cylinders which are not electrically grounded, and the plasma extends for a distance of at least 1 metre from the tip of the electrode to the plasma outlet.

6. A process according to any of claim 1, characterised in that the plasma comprises an atomised surface treatment agent.

7. A process according to claim 6, characterised in that the atomised surface treatment agent is incorporated in the flow of process gas from the inlet to the outlet of the housing.

8. A process according to claim 7, characterised in that the surface treatment agent is atomised within the housing by a combined atomiser and electrode using the plasma process gas as atomising gas for the surface treatment agent.

9. A process according to claim 6, characterised in that the atomised surface treatment agent is injected into the plasma downstream from the electrode through an inlet angled towards the outlet of the housing.

10. A process according to claim 1, characterised in that the plasma is generated at the tip of a single electrode positioned within the dielectric housing.

11. An apparatus for plasma treating a surface, comprising
a dielectric housing having an inlet and an outlet,
means for causing a process gas to flow from the inlet to the outlet,
means for generating a non-equilibrium atmospheric pressure plasma in the process gas,
a tube formed at least partly of dielectric material extending outwardly from the outlet of the housing, whereby the end of the tube forms the plasma outlet and the plasma extends from the electrode to the plasma outlet, and means for moving the surface to be treated relative to the plasma outlet while maintaining the surface adjacent to the plasma outlet.

12. An apparatus according to claim 11, characterised in that the tube of dielectric material is flexible.

13. An apparatus according to claim 11, characterised in that the tube comprises lengths of dielectric material joined by conductive cylinders which are not electrically grounded.

14. An apparatus according to claim 13, characterised in that the conductive joining cylinders have a rounded sharp edge at each end.

15. An apparatus according to claim 11, characterised in that the means for generating a plasma in the process gas comprises a single electrode positioned within the dielectric housing and means for applying a radio frequency high voltage to the electrode to generate an atmospheric pressure plasma at the sharp tip of the electrode.

16. An apparatus according to claim 11, characterised in that it further comprises an atomiser for a surface treatment agent positioned within the housing and means for feeding the process gas to the atomiser to act as the atomising gas.

17. An apparatus according to claim 11, characterised in that it further comprises means for injecting an atomised surface treatment agent into the plasma within the housing.

18. A process according to claim 2, characterised in that the plasma extends for a distance of at least 30 mm from the tip of the electrode to the plasma outlet.

19. A process according to claim 4, characterised in that the tube comprises lengths of dielectric material joined by conductive cylinders which are not electrically grounded, and the plasma extends for a distance of at least 1 metre from the tip of the electrode to the plasma outlet.

20. A process according to claim 18, characterised in that the tube comprises lengths of dielectric material joined by conductive cylinders which are not electrically grounded, and the plasma extends for a distance of at least 1 metre from the tip of the electrode to the plasma outlet.
